(19) United States
(12) Patent Application Publication
(10) Pub. No.: US 2018/0337636 A1
(43) Pub. Date: Nov. 22, 2018

(54) DIGITALLY CALIBRATED AMPLIFIER HAVING AN ALTERNATIVE OUTPUT SIGNAL PATH

(71) Applicant: Avnera Corporation, Beaverton, OR (US)

(72) Inventors: Gilbert C. Martinez, Portland, OR (US); Amit Kumar, Portland, OR (US); Ali Hadiashar, Portland, OR (US); Mark Gehring, Portland, OR (US); Wai Lee, Portland, OR (US)

(21) Appl. No.: 15/984,250

(22) Filed: May 18, 2018

Related U.S. Application Data
(60) Provisional application No. 62/508,185, filed on May 18, 2017.

(51) Int. Cl. H03F 1/02; H03F 3/183; H03M 1/00; H03M 3/00; H03G 3/30

(52) U.S. Cl. CPC H03F 1/0205; H03F 3/183; H03M 1/002; H04R 1/1091; H03G 3/3005; H03F 2200/03; H03F 2200/451; H03M 3/38

(57) ABSTRACT

An audio system can include an amplifier having two parallel drivers, one having common source transistors and one having common drain transistors, also called source following. At low signals, the source followers dominate the open-loop gain signal path, while large signals cause the common source transistors to be dominant. At low signal amplitudes, the common source transistor gain is reduced and the common drain transistors provide the load current. At a pre-determined level of signal amplitude, the common source transistors take over and provide the current load. A calibration system for a DAC is also provided. The calibration system measures individual cell performance in the DAC, then stores its digital equivalent in a coefficient storage. Then, a quantizer can refer to the stored coefficients when selecting the appropriate final quantized digital value.

### CROSS REFERENCE TO RELATED APPLICATIONS

This application is a non-provisional of and claims benefit to co-pending U.S. Provisional Patent Application No. 62/508,185, entitled HEADPHONE AMP, filed May 18, 2017, the contents of which are incorporated herein by reference.

### FIELD OF THE INVENTION

This disclosure is directed to amplifiers, and more specifically, to an amplifier that may be digitally calibrated and includes an alternative output path, and which may be especially well suited as a headphone amplifier.

### BACKGROUND

Many product specifications call for reduced amounts of operating current. This is especially true for battery powered electronics. It is increasingly important that mobile phones and associated hardware operate efficiently, as these devices are carried on the person and are oftentimes away from any charging source for long periods of time.

Reducing operating current in headphone amplifiers is one way to reduce overall current. Headphones are predominantly driven by amplifiers with Class-AB output stage which has low operating current in the quiescent condition. However, there is a limit to how far the output stage quiescent current may be reduced. For example, Miller compensation is commonly used in the Class-AB output stages where high load current boosts the transconductance of the output transistor in order for the output stage to have sufficient voltage gain for Miller compensation to work. But such compensation is less effective in the quiescent condition where the low quiescent bias current in the output transistors are too small to provide much transconductance. There is a limit as to how much the quiescent bias current can be reduced before the output stage gain is too low to support Miller compensation. Adding a series gain stage could boost the gain of the output stage so that Miller compensation would be again effective, but the output device transconductance could increase under high load conditions and with too much gain and bandwidth, the output stage can become unstable.

Also, output amplifiers of Class AB amplifiers are typically preceded by an intermediate low-pass filter to remove the large amount of DAC quantization noise that would otherwise overwhelm and cause distortion in the output amplifier. But such filters contribute noise and power consumption to the overall system that may be unacceptable in some cases.

Embodiments described in this disclosure address these and other limitations of the prior art.

### BRIEF DESCRIPTION OF THE DRAWINGS

FIG. 1 is a block circuit diagram illustrating a conventional amplifier system.

FIG. 2 is a block circuit diagram illustrating a calibration system that may be used in an amplifier system according to embodiments of the invention.

FIG. 3 is a detailed circuit diagram illustrating additional detail of the Digital to Analog Converter illustrated in FIG. 2.

FIG. 4 is a circuit diagram illustrating an amplifier architecture including an alternative output path according to embodiments of the invention.

FIG. 5 is a circuit diagram illustrating an output stage of the amplifier illustrated in FIG. 4.

### DETAILED DESCRIPTION

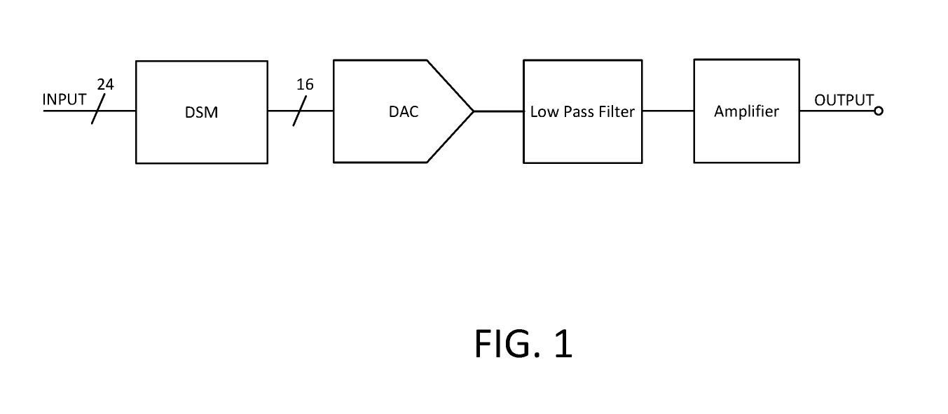

FIG. 1 is a block circuit diagram illustrating a conventional headphone amplifier system. A Delta-Sigma Modulator (DSM) operates as a quantizer that down-converts a higher-bit digital signal into a lower bit one. For example, as illustrated, a DSM converts a 24-bit digital signal into a 16-bit digital signal. Of course, the illustrated embodiment is only an example, and other bit rate conversions by the DSM are possible. A Digital to Analog Converter (DAC) converts the quantized digital signal to an analog signal, which is then amplified by an amplifier after passing through a low pass filter. The low pass filter removes much of the high frequency noise to avoid inducing nonlinearity in the amplifier. As mentioned above, the low pass filter is a source of noise as well as power consumption, both of which are to be avoided, especially in battery powered electronics.

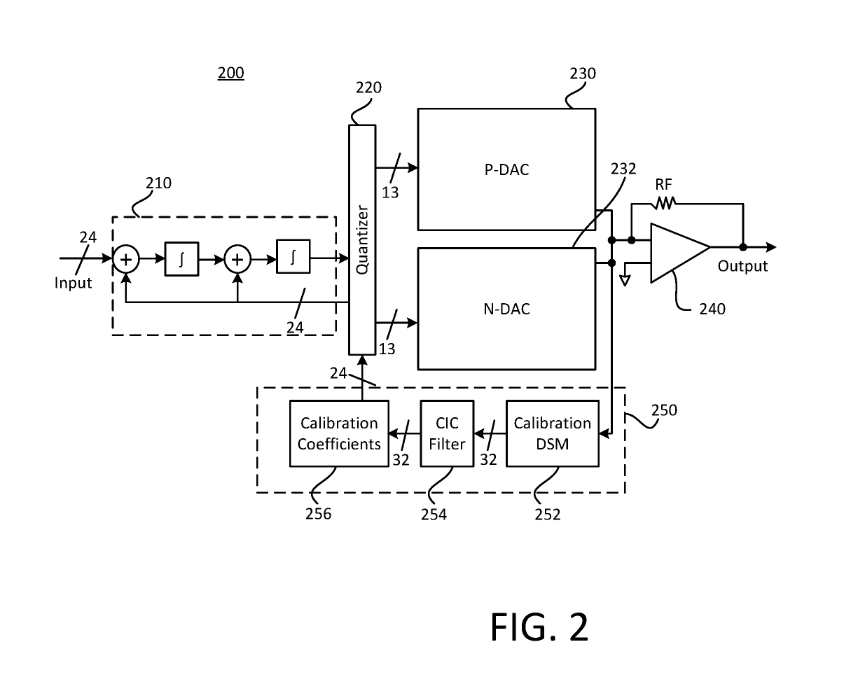

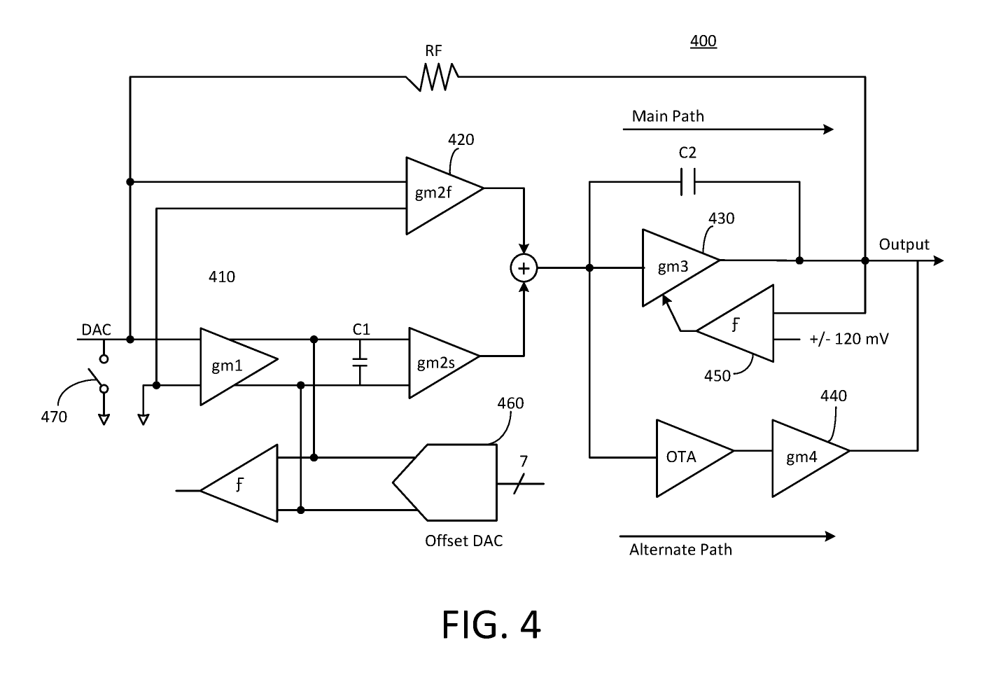

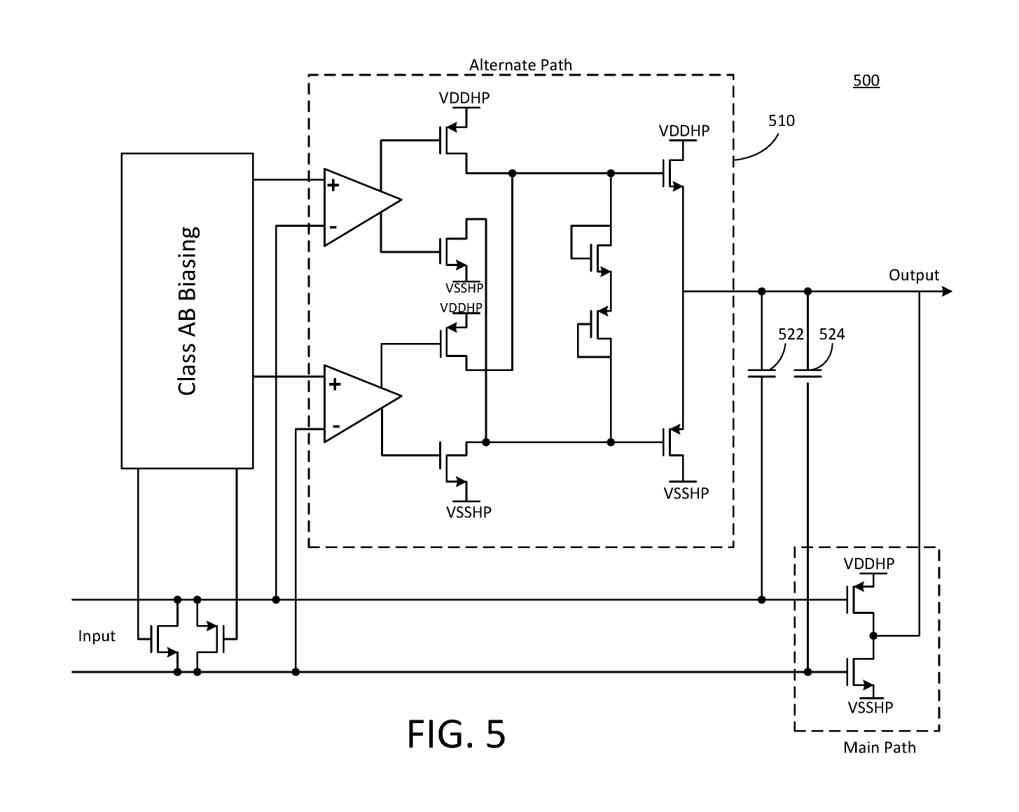

FIG. 2 is a block circuit diagram illustrating a calibration system that may be used in an amplifier system 200 according to embodiments of the invention. The amplifier system 200 generally includes a loop filter 210, a quantizer 220, one or more Digital to Analog converters (DACs) 230, 232, and an output amplifier 240, which is discussed in detail with reference to FIGS. 4 and 5 below. A calibration system 250 corrects for errors that would otherwise be present in the digital-to-analog conversion, as described below.

The DACs 230, 232 and other analog portions of the amplifier system 200 may operate from ±1.2 volt power supplies, although, as described below, output stages of the amplifier 240 may operate from a dynamically switched power supply with ±1.1 volt, ±1.65 volt, and ±2.2 volt supplies for efficient Class G operation. Using complementary transistors for the voltage supply allows the amplifier to be ground referenced, which simplifies the output structure to an operational amplifier and a single feedback resistor, as illustrated in FIG. 2.

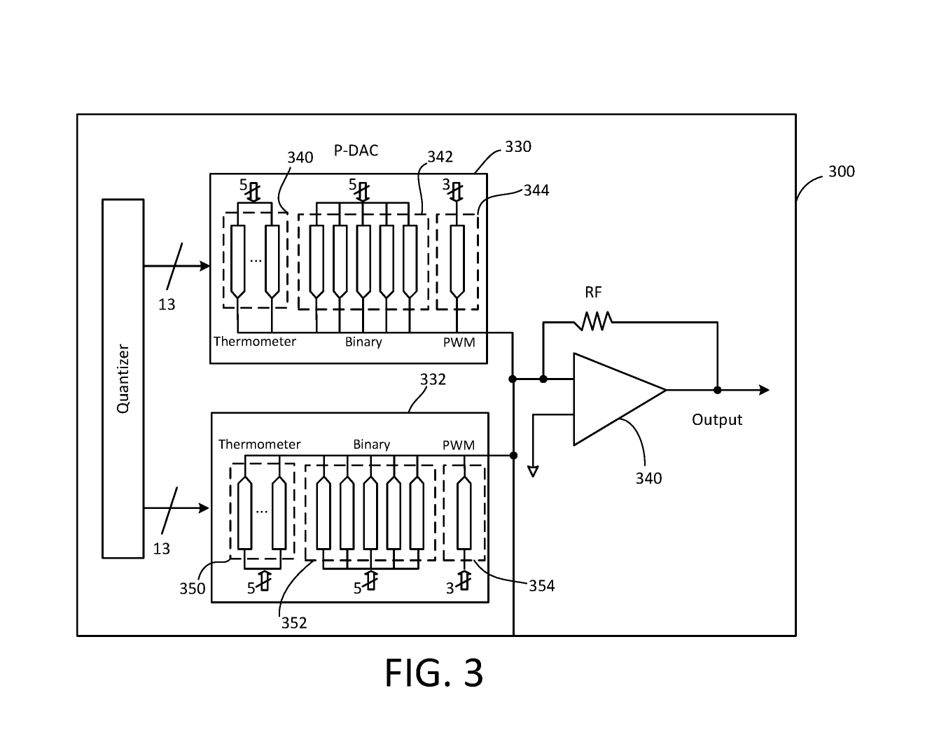

FIG. 3 illustrates an example implementation of a P-DAC 330 and an N-DAC 332, which may be examples of the DACs 230, 232 illustrated in FIG. 2. The DACs 330, 332 may be independently operated. For example, if the amplifier output is a negative voltage, then the P-DAC 330 is operational while the N-DAC 332 is non-operational. This minimizes power consumption and noise contribution to only the P-DAC or N-DAC that is needed. In some embodiments the P-DAC 330 is made from current sourcing p-type transistors while the n-DAC 332 is made from current sinking n-type transistors.

Each of the P-DACs 330, 332 are functionally identical, although this is not required in all embodiments. In FIG. 3, each of the P-DAC 330 and N-DAC 332 include three segments of cells—a thermometer segment 340, 350, a binary segment 342, 352, and a pulse width segment 344, 354. Each of the segments include a number of cells, each of which independently operate based on bits passed to each segment. For example, the thermometer segment 340 includes 31 bit-cells that operate when a five-bit number is passed to the segment. In the thermometer segment 340, each of the bit cells may generate the same amount of current when energized, such as 10 μA. The binary segment 342 may also receive five bits, which directly control five cells in the binary segment 342. The bit cells in the thermometer segment 340 may be individually powered down dynamically when they are not needed, such as during low audio conditions. When the binary segment 342 and the pulse width segment 344 provide enough range to completely and accurately generate the analog signal from the digital signal passed to it, the thermometer segment 340 may be completely shut down to conserve power. In one embodiment the DACs 330, 332 operate at 1.536 MHz, and reserve approximately one-half of the unit interval, or between approximately 240-325.5 ns, to turn on the bit cells in the thermometer segment and allow them to become settled. The thermometer segment 350 in the N-DAC 332 operates similarly to the thermometer segment 340 in the P-DAC 330.

Differently than the thermometer segment 340, the cells in the binary segment 342 may be binary weighted by the amount of current each cell generates when energized. For example, in one embodiment the binary cells may be set to generate 5 μA, 2.5 μA, 1.25 μA, 0.625 μA and 0.312 μA, respectively, when energized. This segment 342 is referred to as the binary segment due to this binary progression of cell weights. The pulse width segment 344 is the least significant bit. In one embodiment the pulse width segment 344 includes only a single bit cell. This bit is pulse-width modulated to produce ⅛ fractions of the bit cell output based on a three-bit digital input. Also, differently than the thermometer segment 340, in some embodiments the binary segment 342 and the pulse width segment 344 remain powered at all times. Depending on the application, it is possible that the binary segment 342 and/or the pulse width segment 344 could also be dynamically powered, depending on content, to save additional power.

As described with reference to FIG. 3, the DACs 230, 232 of FIG. 2 are made of a number of DAC elements that have manufacturing tolerances making the transfer function of the DACs non-linear. In other words, unless compensated, the DACs 230, 232 would otherwise not faithfully output a true analog representation of the digital signal provided to it. A calibration system 250 works to eliminate or minimize DAC nonlinearity caused by the DAC element variations thus allowing the DACs 230, 232 to be extended to high resolution with a very low amount of quantization noise compared to conventional Delta-Sigma DACs. Reducing the errors of the DACs 230, 232 through calibration, as well as through the other techniques described herein, allows the DACs 230, 232 to drive the output amplifier 240 directly, saving the need to include an intermediate filter stage that would otherwise unnecessarily introduce noise and power consumption.

With reference back to FIG. 2, the calibration process begins at startup, when the amplifier system 200 is initially powered. When initially powered, the amplifier system 200 enters a calibration stage. In the calibration stage, output of each of the cells within the DACs 230, 232 are individually measured by a calibration Analog to Digital Converter (ADC), which is referred to in FIG. 2 as a calibration DSM (Delta-Sigma Modulator) 252. In this embodiment, only one calibration DSM 252 is necessary, and it individually steps through all of the bit cells sequentially performing its measurements. In some embodiments, the DSM 252 is a first-order, continuous-time, Delta-Sigma ADC clocked at 6.144 MHz and completes each measurement in approximately 2.66 ms. Measuring all of the bits in the DACs 230, 232 may take approximately 200 ms, for example.

The current in the cells of the thermometer segments 340, 350 and binary segments 342, 352 are static, while the current in the cells of the pulse width segments 344, 354 are duty-cycled. After filtering the output in a CIC filter 254, each of the individual cells' measured weight is stored in a lookup table. The lookup table is illustrated in FIG. 2 as a store of calibration coefficients 256.

In operation, the mismatched bit cells in the DACs 230, 232 are corrected in the digital domain, i.e., before being sent to the DACs 230, 232. To perform such correction, the quantizer 220 refers to the stored calibration coefficients in the coefficient store 256 as it is determining which binary values to output to the DACs 230, 232. As the bits are sent to the quantizer 220, the quantizer uses the actual measured weights that were stored in the coefficient store 256 to select the DAC code that best matches the data word input to the quantizer. The quantizer 220 sums the known weights of the bit cells as selected by the DAC code and feeds back the digital equivalence of the analog current output to the calibration DSM 252, using the loop filter 210. Since the digital feedback of the DSM 252 precisely matches the analog output of the DAC 230, 232, the mismatch of the individual bit cells is also fed back and noise shaped by the loop filter 210. Thus, this process compensates for the mismatched bit cells in the DACs 230, 232.

FIG. 4 is a circuit diagram illustrating an amplifier architecture 400 including an alternative output path according to embodiments of the invention. The amplifier 400 is a second-order amplifier that includes a high-gain first stage 410 and a feedforward path 420, for stability. Following the first stage 410 are two different Class AB paths, a main path through amplifier 430 as well as an alternate path through amplifier 440. The main and alternate paths are optimized separately. The main path through amplifier 430 is optimized for rail-to-rail output swing, for large signals, while the alternate path through amplifier 440 is optimized for low-quiescent current operation. A comparator 450 monitors the output signal level and determines which of the main or alternate signal paths will dominate by adjusting a bias current of the main path output transistors in the amplifier 430.

The comparator 450 monitors the output signal level. When the output signal is below ±120 mV, the output of the comparator 450 sets the bias current in the amplifier 430 to be very low, which severely reduces the current gain through the main path. Under such conditions the current gain of the alternate path dominates the open loop gain of the amplifier 400.

FIG. 5 shows an example circuit architecture 510 that may be used as the alternate path of the amplifier 400 of FIG. 4. The architecture 510 includes a complementary Class AB source follower output and common source driver amplifiers to boost gain. Since the gain of the source follower output stage is limited to one, even with substantial load current, the alternative path gain range is bounded and stability is easily controllable. For output signals greater than ±120 mV, the bias current in the main path is increased and the main path gain increases to dominate the output signal voltage. The main path output stage is a conventional complementary common-source amplifier topology for rail-to-rail output swing and high load drive capabilities. Capacitors 522 and 524 provide Miller compensation for both output stage paths.

Referring back to FIG. 4, an offset DAC 460 helps to avoid quiescent power loss due to DC offset load current. The first gain stage amplifier 410 provides the dominant offset mechanism. On startup, only the first stage amplifier 410 is enabled and its amplifier input is shorted to ground through switch 470. Inputs to the offset DAC 460 are swept from zero until the output of the DAC 460 causes the output of the first stage amplifier 410 to be nulled.

Typically, performing such a nulling process produces a pop or click through the headphones, which is unpleasant for the user. In embodiments of the invention, the calibration process is performed before the output stages are enabled, and therefore there are no audible pop and click artifacts during the offset calibration process. Instead, the output stages of the amplifier 400 are enabled only after the calibration is complete.

Embodiments of the invention may be incorporated into integrated circuits such as sound processing circuits, or other audio circuitry. In turn, the integrated circuits may be used in audio devices such as headphones, mobile phones, portable computing devices, sound bars, audio docks, amplifiers, speakers, etc.

Having described and illustrated the principles of the invention with reference to illustrated embodiments, it will be recognized that the illustrated embodiments may be modified in arrangement and detail without departing from such principles, and may be combined in any desired manner. And although the foregoing discussion has focused on particular embodiments, other configurations are contemplated.

In particular, even though expressions such as “according to an embodiment of the invention” or the like are used herein, these phrases are meant to generally reference embodiment possibilities, and are not intended to limit the invention to particular embodiment configurations. As used herein, these terms may reference the same or different embodiments that are combinable into other embodiments.

Consequently, in view of the wide variety of permutations to the embodiments described herein, this detailed description and accompanying material is intended to be illustrative only, and should not be taken as limiting the scope of the invention.

What is claimed is:

1. A Digital to Analog Converter (DAC) having compensation, comprising:
a series of bit cells each producing an output when energized;
a measurer configured to determine an output of one or more of the series of bit cells when such cell is energized;
a coefficient store configured to store calibration coefficients derived from the measured bit cells; and
a quantizer configured to generate a digital input for the DAC using input from the coefficient store.

2. The DAC according to claim 1 in which the series of bit cells, if uncompensated, produces a non-linear output based on a linear input.

3. The DAC according to claim 1 in which the quantizer receives a digital input at a first input and generates a modified digital output at least partially based on the coefficient store.

4. The DAC according to claim 4, further comprising a loop filter having a first input for accepting a digital input, having a second input for accepting an input from the quantizer, and having an output coupled to the first input of the quantizer.

5. The DAC according to claim 1 in which the series of bit cells include a first set configured as a thermometer portion, a second set configured as a binary portion, and a third set configured as a pulse-width modulation portion.

6. The DAC according to claim 5 in which the bit cells in the thermometer portion may be set to a powered down state when not in use.

7. The DAC according to claim 6 in which the bit cells in the thermometer portion are structured to be energized from the powered down state within a single cycle of the DAC.

8. The DAC according to claim 6 in which the bit cells in the thermometer portion are structured to be energized from the powered down state within approximately one-half of a single cycle of the DAC.

9. The DAC according to claim 8 in which a single cycle of the DAC is approximately 650 ns in duration.

10. An amplifier for amplifying an analog audio signal and producing an amplified output audio signal, the amplifier comprising:
an input for accepting the analog audio signal;
an output monitor configured to determine when the output audio signal exceeds a first output threshold;
a first output path coupled to the output monitor, the first output path for amplifying the audio signal when the output audio signal is below the first output threshold; and
a second output path for amplifying the audio signal when the output audio signal is above the first output threshold.

11. The amplifier according to claim 10, in which the first output path comprises an source-follower connected amplifier.

12. The amplifier according to claim 11, in which the second output path comprises a common drain connected amplifier.

13. The amplifier according to claim 10 further comprising a feedback resistor coupled between the input and the output of the amplifier, in which the feedback resistor produces a voltage output for the amplifier.

14. The amplifier according to claim 10 in which the output monitor is a threshold comparator.

15. The amplifier according to claim 14 in which a first input of the threshold comparator is coupled to the output audio signal and in which a second input of the threshold comparator is coupled to a 120 mV voltage source.

16. The amplifier according to claim 14 in which an output of the threshold comparator is coupled to the second output path and structured to reduce an output gain from the second output path.

17. The amplifier according to claim 10, further comprising a calibrator configured to reduce quiescent output from the amplifier when the input audio signal is off.

18. The amplifier according to claim 17, in which the calibrator comprises a Digital to Analog Converter (DAC).

19. The amplifier according to claim 17 in which the output of the DAC is coupled between a first and second preamplifier.

20. The amplifier according to claim 19 in which the output of the DAC compensates the output of the first preamplifier prior to sending the combined output from the first preamplifier and the output of the DAC to the second preamplifier.
